(19) United States
(12) Patent Application Publication
(10) Pub. No.: US 2025/0390625 A1
(43) Pub. Date: Dec. 25, 2025

(54) SIMULATOR AND METHOD FOR SIMULATING SENSOR FOR OBJECT DETECTION

(71) Applicant: dSPACE GmbH, Paderborn (DE)

(72) Inventors: Christoph BRODEHL, Paderborn (DE); Thomas GLARNER, Paderborn (DE)

(73) Assignee: dSPACE GmbH, Paderborn (DE)

(21) Appl. No.: 19/241,916

(22) Filed: Jun. 18, 2025

(30) Foreign Application Priority Data
Jun. 19, 2024 (DE) 102024117275.4
Jun. 19, 2024 (EP) 24183111.4

(51) Int. Cl. G06F 30/15

(52) U.S. Cl. CPC G06F 30/15

(57) ABSTRACT

A simulator for simulating a sensor for object detection. The simulator is set up to generate synthetic sensor data of the sensor by the simulation. A visibility module generates object data for at least one virtual object located in a virtual environment as a function of the sensor. A mapping module determines at least two parameters of the virtual object from the object data and represents at least one virtual object as a function of the at least two parameters in a first mapping. A link module transfers the first mapping to a second mapping taking into account a characteristic function of the sensor. In the second mapping, the at least one virtual object is represented as a function of the at least two parameters. An output module converts the second mapping into the synthetic sensor data and provides the synthetic sensor data for output.

This nonprovisional application claims priority under 35 U.S.C. § 119(a) to European Application No. 24183111.4, which was filed on Jun. 19, 2024, and to German Patent Application No. 10 2024 117 275.4, which was filed in Germany on Jun. 19, 2024, and which are both herein incorporated by reference.

### BACKGROUND OF THE INVENTION

### Field of the Invention

The present application relates to a simulator and a method for simulating a sensor for object detection as well as a computer program product.

### Description of the Background Art

Devices for performing control and/or regulation tasks in vehicles are also referred to as control units. Control units in vehicles, especially motor vehicles, may have a computing unit, memory, interfaces, and possibly other components that are necessary for the processing of input signals with input data into the control unit and the generation of control signals with output data. The interfaces are used to record the input signals or to output the control signals.

Control units for driving functions for both advanced driver assistance systems (ADAS=Advanced Driver Assistance Systems) and autonomous or semi-autonomous driving can receive sensor data from various sensors, e.g., sensors for object detection, as input data.

A way to test control units that evaluate sensor data from sensors is to test the control units with the corresponding sensors in the installed state—for example in the motor vehicle as part of test drives. This is time-consuming, cost-intensive and many situations cannot be checked in a real environment, as they only occur in extreme cases, such as accidents. For this reason, corresponding control units are tested in artificial environments, for example in test benches. Another common test scenario is to test the functionality of a control unit by means of a simulated environment in a so-called virtual environment. Environmental simulation can include the simulation of real sensors by means of a sensor simulation. The sensor simulation can generate synthetic sensor data that replicates the virtual environment of the control unit.

It is known from Stefan O. Wald, Frank Weinmann: Ray Tracing for Range-Doppler Simulation of 77 GHz Automotive Scenarios, 13th European Conference On Antennas and Propagation (2019) that so-called ray tracing is used to determine a range-Doppler map. In a virtual environment, a propagation path is analytically calculated using the positions of the transmitter, the scattering centers, and the receiver. This can then be used to determine and further use synthetic range-Doppler maps.

### SUMMARY OF THE INVENTION

It is therefore an object of the present invention to provide a simulator for simulating a sensor for object detection, the simulator being set up to generate synthetic sensor data from the sensor for object detection by means of a simulation. The simulator has a visibility module, a mapping module, a link module, and an output module.

The visibility module can be set up to generate object data for at least one virtual object that is located in a virtual environment, as a function of the sensor.

The mapping module can be set up to determine at least two parameters of the virtual object from the object data and to display the at least one virtual object as a function of the at least two parameters in a first mapping.

The link module can be set up to transfer the first mapping to a second mapping, taking into account a characteristic function of the sensor, wherein the second mapping shows the at least one virtual object as a function of the at least two parameters.

The output module can be set up to convert the second mapping into the synthetic sensor data and provide the synthetic sensor data for output.

A method for simulating a sensor for object detection generates synthetic sensor data from the sensor. The method comprises: generating object data for at least one virtual object that is located in a virtual environment. The object data is generated as a function of the sensor for object detection; determining at least two parameters of the virtual object from the object data and representing the at least one virtual object as a function of the at least two parameters in a first mapping; transferring the first mapping into a second mapping, taking into account a characteristic function of the sensor, wherein in the second mapping the at least one virtual object is represented as a function of the at least two parameters; and converting the second mapping into the synthetic sensor data and providing the synthetic sensor data for output.

A computer program product includes the commands that, when a computer executes a program, cause it to perform the steps described in the method.

By means of the simulator and the device described, the generated synthetic sensor data can be adapted even better to the requirements placed on the synthetic sensor data.

The simulator for simulating the sensor for object detection and the method for simulating the sensor for object detection make it possible to calculate partially processed sensor data in real-time. The synthetic sensor data provided for output can represent synthetic sensor data, which simulates data that exists within the sensor as partially processed sensor data. This makes it possible to make such partially processed sensor data available as part of the synthetic sensor data and to process it further within a simulation that uses the synthetic sensor data.

The simulator and the method can do without the simulation of concrete, detailed technical processes in the sensor. It is only necessary to provide the characteristic function that characterizes the sensor. However, this is measurable, for example, and does not require a disclosure of know-how about the concrete, detailed technical structure of the sensor by the respective sensor manufacturer.

The simulator for sensor simulation for object detection can avoid the use of an actual object detection sensor, which can reduce testing efforts. For example, the object detection sensor can have a radar sensor, a lidar sensor, and/or an ultrasonic sensor. The simulator simulates such a sensor as intended.

The simulator uses a virtual environment with at least one virtual object to generate the synthetic sensor data, which can then be used for further processing. This means that a test setup with a sensor and an object simulator is no longer necessary, but instead the sensor and the synthetic sensor data generated by it can be simulated using a virtual environment with virtual objects on one or more computers. Therefore, the simulator has one or more computers and/or processors with corresponding memory and input and output interfaces.

Ideally, the synthetic sensor data generated by the simulation of the sensor should be indistinguishable from the sensor data generated by the sensor, such as a radar sensor. The synthetic sensor data can then be further processed, for example, by the control unit and/or a simulation of the control unit.

For the virtual environment with at least one virtual object, the visibility module generates the object data that the sensor would have generated in a real environment with real objects. The visibility module can therefore be designed as a software function. The visibility module can also run on one or more processors associated with this software function, such as graphics processors.

The mapping module can also be designed as a software module. It creates the first mapping with at least two parameters of the virtual object from the object data. When two parameters are used, the first mapping can be thought of as a two-dimensional diagram that maps the two parameters to a function value. If more than two parameters are used, a correspondingly higher-dimensional first mapping is available.

The first mapping is a representation as determined by the first mapping from the object data. In the first mapping, characteristics of the sensor are still missing. These are inserted by the link module, which can also be designed as a software function. The link module uses the first mapping and the sensor's characteristic function to determine the second mapping.

The characteristic function of the sensor reflects the properties of this sensor. This means, it can be determined on the basis of test data supplied from output data from the sensor. The second mapping therefore provides a more realistic representation through the at least two parameters of the at least one virtual object. This can then be used to take into account effects that are caused, for example, by edge effects, mapping artifacts or other realistic properties of the sensor.

The output module can be a software function that transfers the second mapping to synthetic sensor data and makes it available for output. With this synthetic sensor data, it is then possible to carry out further processing steps, e.g., to test control units.

The same applies to the method and the computer program product.

In an example, the first mapping can have a first range-Doppler map, and the second mapping can have a second range-Doppler map. In the range-Doppler map, the range of objects is plotted in a two-dimensional graph over their relative velocity to the sensor. So the two parameters are range and relative speed. The first range-Doppler map is thus transferred to the second range-Doppler map by the link module.

Measuring a Doppler shift provides a way to measure velocity directly, such as a sensor signal reflected on the object, such as a radar echo or a lidar echo. If, for example, an object approaches the sensor, the frequency of the object's echo signal is slightly increased as compared to the emitted signal. Conversely, a reduced frequency means that the object is moving away from the sensor. The Doppler shift is higher the faster the object moves relative to the sensor and thus allows for a direct conclusion to be drawn about the relative radial velocity of the object.

An example of the sensor for object detection is the Frequency Modulated Continuous Wave (FMCW) radar. Such an FMCW radar emits a continuous radar signal, the chirp signal. The signal is an uninterrupted, periodic sequence of signal sections with variable frequency (chirps). The signals reflected by objects are accordingly time-shifted chirps. The time offset and the changing frequency result in a small difference in frequency between the chirp signal and the echo signal. In a mixer of the radar, the emitted signal, the chirp signal, is superimposed with the echo signals. This creates a beat with a beat frequency for each echo signal, with the beat frequency being higher the further away the respective object is from the sensor. From the beat, the sensor forms the Fourier transform. In the Fourier transform, each echo signal, i.e., each reflected object, is visible as a peak corresponding to the respective beat frequency, and from whose position on the frequency axis the range of the object can be immediately deduced.

A Fourier transform is determined by the sensor for each individual chirp. The individual results of this Fourier transform are combined. This results in a two-dimensional range-time mapping with the range in the vertical and the time in the horizontal. In the vertical (range) the individual Fourier transforms are plotted. Along the horizontal axis, a large number of Fourier transforms are then plotted in a temporal sorting.

The sensor then subjects the range-time map to a second Fourier transform along the time axis. The result is the so-called range-Doppler map. In each row of the range-time map, the phase of the values along the timeline changes. The horizontal position in the range-Doppler map indicates the frequency of the phase cycles of the object, i.e., the phase change over time. This phase change is the frequency shift of the radar echo due to the relative motion of the object. Each peak in the range-Doppler map thus stands for an object detected by radar. From the vertical position of the peak, the range of the object can be read, from the horizontal position of its radial relative velocity. Such a range-Doppler map can also be used, for example, with a lidar sensor, if the lidar sensor functions in the same way according to the FMCW principle.

In particular, the characteristic function can have a point spread function of the sensor and the link module can be set up to transfer the first mapping to the second mapping by performing a convolution function with the point spread function. The characteristic function can be the point spread function of the sensor, and the first range-Doppler map can be transferred to the second range-Doppler map by a convolution with the point spread function.

In high-frequency technology, for example, a point spread function of a sensor describes the effect of band-limiting influencing factors such as diffraction phenomena at apertures, a mapping error or an influence of the sensor surface or an aperture if the sensor is a radar or a lidar in optics, but also in image processing.

The point spread function specifies how an idealized, point-like object would be mapped by a system (i.e., the sensor). Often, the form of the response is independent of the original location of the ideal point-like object. In this case, this is called a linear system, and the total response of the system can be calculated as the sum of the point responses of the object broken down into its points. The convolution causes each point-like local maximum in the first mapping to be replaced by a functional curve corresponding to the point spread function.

The object detection sensor can have an active sensor, which is set up to generate raw sensor data by emitting a chirp signal and receiving an echo signal and to determine the second mapping from the raw sensor data. An active sensor is a sensor that emits a signal, also known as a chirp signal, to detect objects in its environment, which is reflected by objects in the environment via an echo signal. Using the echo signal, it is then possible to detect the objects and observe their movement relative to the sensor over time. Active sensors therefore include radar, lidar or acoustic sensors that emit chirp signals and then evaluate the corresponding echo signals.

A recalculation module can be provided, which can be designed as a software function, wherein the recalculation module determines synthetic sensor raw data from the second mapping, wherein the determination of the synthetic sensor raw data depends on the sensor for object detection. Access to synthetic sensor raw data may become important for the further processing of synthetic sensor data in a simulation of the sensor in the future.

By means of the simulator or the method, the second mapping can be determined from the object data. It is therefore possible to provide synthetic sensor data for output, which has the object data and the second mapping. The determination of synthetic sensor raw data is optional, but not mandatory. Dispensing with the calculation of the synthetic sensor raw data enables efficient and fast calculation and cost-effective implementation.

The determination of the synthetic sensor raw data by the recalculation module has an inverse Fourier transform. From the raw sensor data, a Fourier transform can be used to determine the second mapping. Therefore, an inverse Fourier transform can be used for a recalculation.

A virtual position can be assigned to the simulated sensor in the virtual environment and the object data for the at least one virtual object is generated cyclically, taking into account the respective virtual position, e.g., by the visibility module.

For example, so-called ray tracing can be used for this purpose, in which the emission of a virtual chirp signal and the respective virtual echo signal on a virtual object are calculated in the virtual environment. The object data for a given virtual object can have a representation of the respective virtual echo signal of the respective virtual chirp signal on the respective virtual object.

The synthetic sensor data is designed in examples of the simulator and the method in such a way that the object data can be derived by the sensor from the synthetic sensor data. The synthetic sensor data is therefore of such a quality that it could also be real sensor data and could be processed by the real sensor.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of a simulation environment,

FIG. 2 shows a conversion of sensor object data to a second mapping,

FIG. 3 shows a virtual environment with virtual objects,

FIG. 4 shows a range-Doppler map from object data,

FIG. 5 shows a characteristic function,

FIG. 6 shows a second mapping,

FIG. 7 shows a generation of the second mapping, and

FIG. 8 shows a flowchart.

### DETAILED DESCRIPTION

FIG. 1 shows a simulation environment 40, which has a simulator 10, a virtual environment 30 and an application 36. The simulator 10 is designed to simulate an object detection sensor such as a radar or lidar sensor.

For example, the application 36 is an automated control of a vehicle on which the simulated sensor 38 is to be arranged. But other driver assistance functions can also be such applications 36. The application 36 can also be at least partially designed as hardware and, for example, be designed as a control unit or at least as part of a control unit.

This structure of the simulation environment 40 according to FIG. 1 can be purely virtual and run on one or more computers, for example. This allows for signal processing to be simulated and/or applications 36 such as driving functions to be tested without a time-consuming and cost-intensive test setup.

The structure of the simulation environment 40 according to FIG. 1 can also be implemented partly in hardware and partly in software.

In the virtual environment 30, desired scenarios can be represented with one or more virtual objects O1-O6. How these virtual objects O1-O6 move relative to the simulated sensor 38 can also be simulated realistically. Specifically, the application 36 can interact with the virtual environment 30, for example, through the application data and the synthetic sensor data 32.

The simulator 10 has a visibility module 12 that generates object data 22 for at least one virtual object O1-O6 in the virtual environment 30 as a function of the sensor. The object data 22 contains information about the virtual objects O1-O6 such as their existence, range, and direction. The object data 22 can be obtained by means of ray tracing, for example.

The visibility module 12 transfers the object data 22 to a mapping module 14 on the one hand and to an output module 20 on the other. The modules 12, 14 and 20 are preferably designed as software functions. It is possible that a separate hardware may be provided for the execution of these functions, especially if it involves computationally intensive functions such as, e.g., the calculation of a Fourier transform. For example, graphic processors can used for this purpose.

The mapping module 14 determines at least two parameters of the virtual object O1-O6 from the object data 22 and displays the at least two parameters in a first mapping 24. The first mapping 24 is transferred to a link module 16.

The link module 16 transfers the first mapping 24 to a second mapping 26, taking into account a characteristic function 46 of the sensor, wherein in the second mapping 26 the at least one virtual object O1-O6 is shown as a function of the at least two parameters. The second mapping 26 is output from the link module 16 to a recalculation module 18 on the one hand and to the output module 20 on the other.

The recalculation module 18 determines synthetic sensor raw data 28 from the second mapping 26, which the recalculation module 18 passes on to the output module 20. To determine the sensor raw data 28 from the second mapping 26, the recalculation module 18 can use an inverse Fourier transform.

The output module 20 provides synthetic sensor data 32 for output, e.g., to the application 36. The synthetic sensor data 32 is generated from the second mapping 26 and include in particular the information from the second mapping 26. The object data 22 and/or the synthetic sensor raw data 28 can also be taken into account. In particular, the synthetic sensor data 32 is generated by the output module 20 in such a way that it replicates the sensor data of the real sensor being simulated as closely as possible.

The application 36, which determines a trajectory for a vehicle as a function of the synthetic sensor data 32, for example, transmits such application data 34 to the virtual environment 30, so that a movement of the simulated sensor 38 relative to the virtual objects O1-O6 in the virtual environment 30 can be taken into account over time.

The second mapping is designed in such a way that its information corresponds to a processing step within the real sensor, which is simulated by the virtual sensor 38. The above-mentioned characteristic function 46, in particular the point spread function, makes it possible to perform a realistic simulation of the signal processing chain and also to output the intermediate product of the second mapping 26 by the simulator 10. For example, the point spread function characterizes the respective sensor in its mapping properties, so that it can be used to recalculate from the object data to the range-Doppler map as it would be in the sensor to be simulated.

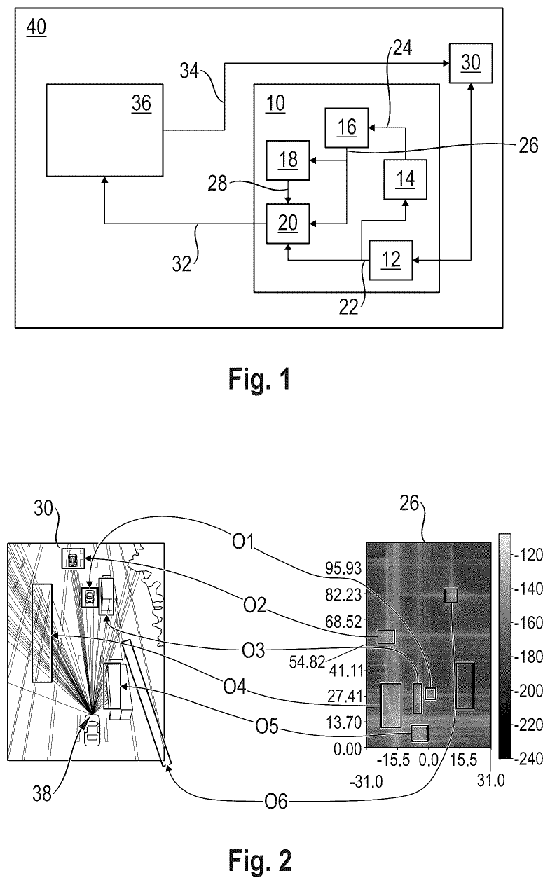

FIG. 2 shows how the different virtual objects O1-O6 simulated in the virtual environment 30 can be found in the second mapping 26. As shown in the left image of FIG. 2, a simulated sensor 38 sends chirp signals to the virtual environment 30 with the objects O1 to O6. For this purpose, so-called ray tracing can preferably be used.

Driver assistance systems that actively observe the vehicle's surroundings and can control the vehicle based on their observations are regularly developed and tested in virtual test environments. In this case, the respective sensor, such as a radar sensor, is completely or partially replaced by a virtual sensor 38, which can also be described as a free-cut.

The virtual sensor 38 emulates the function of the physical real sensor in a realistic way and generates synthetic sensor data 32 to match the virtual test environment 30. As described in FIG. 1, the synthetic sensor data 32 can be generated from the second mapping 26. Optionally, the synthetic sensor data 32 can also be generated from the object data 22.

The synthetic sensor data 32 is fed into the application 36. The application 36 is, for example, an emergency braking assistant, pedestrian detection, and/or an application for fully automatic driving. The synthetic sensor data 32 can be used to check whether the application 36 reacts to situations simulated in the virtual test environment 30 as desired.

The virtual test environment 30 is intended to realistically simulate a field test of the application 36. This means that the entire simulation, including the generation of the synthetic sensor data 32, must run in real time. For example, if an application 36 expects new sensor data every 30 ms, the simulation must provide a complete up-to-date set of synthetic sensor data 32 every 30 ms.

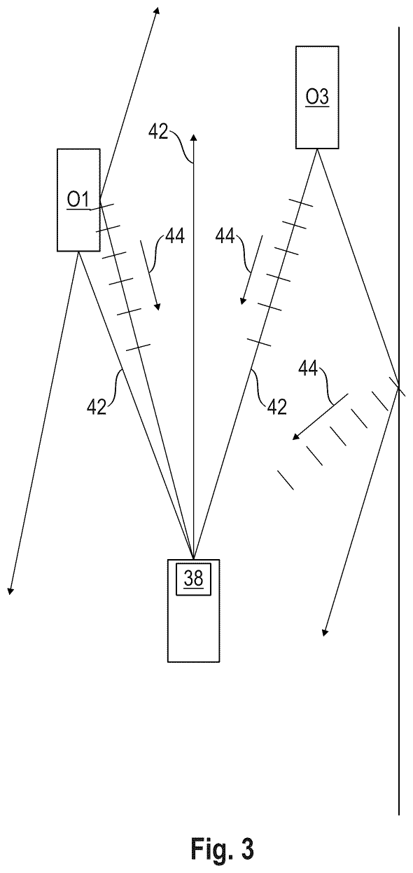

In the virtual environment 30, the virtual objects O1 to O6 can be seen in FIG. 2, where simulated chirp signals 42, which emanate from the simulated sensor 38, are reflected (cf. FIG. 3). The corresponding wavefronts of simulated echo signals 44 (cf. FIG. 3) are received by the simulated sensor 38 and determine the generation of the object data 22, from which the second mapping 26 is then determined, as described in FIG. 1.

On the right side of FIG. 2 is the second mapping 26. The arrows between the left image and the second mapping 26 mark the positions of the objects O1 to O6 in the second mapping 26.

On the abscissa of this second mapping 26, the relative velocity between the simulated sensor 38 and the respective virtual object O1-O6 is entered, and on the ordinate, the range between the simulated sensor 38 and the respective object O1-O6. The brightness in the second mapping 26 can be used to represent a third dimension, namely how strong the echo signal of the respective object is. This is also called a peak. This can indicate the size of the respective object O1-O6, but at least how strongly the respective object O1-O6 reflects the signal emitted by the sensor 38. To the right of the second mapping 26, an assignment of brightness to numerical values is specified.

FIG. 3 shows the example of the ray tracing method used to generate object data 22 in the virtual environment.

Ray tracing is a well-known method for the realistic representation of optical phenomena in computer graphics. In order to calculate an image perceived by a virtual observer, a bundle of geometric light rays is projected into the virtual environment 30 starting from their eyes. By further tracking individual rays using reflection or refraction laws, it is possible to calculate what the observer sees on a reflecting and/or refracting surface. With graphics cards, a calculation of a ray tracing image can be made possible in real time.

In the present case, the observer is the virtual sensor 38 and shown is the adaptation of ray tracing to radar waves, i.e., electromagnetic waves in the radio frequency range. The polygons visible from the virtual sensor 38, i.e., objects O1-O6, in the virtual test environment 30 are bombarded with a virtual geometric beam as a simulated chirp signal 42 and each beam is reflected and tracked according to the laws of geometric optics as a simulated echo signal 44. Due to the properties of electromagnetic waves in the radar range, the simulation is carried out in such a way that each contact of a radar beam as a simulated chirp signal 42 with a polygon generates a local wavefront as a simulated echo signal 44. Each wavefront is simulated as a plane wave directed at the virtual sensor 38. The intensity of this wave depends on the range of the spatial orientation and the material of the respective polygon, i.e., of object O1-O6. The echo measured by the virtual sensor 38 is calculated as the sum of all plane waves of the simulated echo signals 44.

FIG. 3 schematically shows the simulated sensor 38 with the simulated chirp signals 42, the simulated echo signal 44 as a wavefront, wherein only the virtual objects O1 and O3 as well as a side wall are shown here. The side wall can also be one of the objects O1 to O6.

The chirp signal emitted by the sensor 38 in the middle does not cause reflection, but the chirp signals emitted towards the objects O1 and O3 as well as the side wall on the right evoke echo signals 44 as plane wavefronts (far-field approximation). At the sensor 38, the echo signals 44 are superimposed, wherein the simulated sensor 38 then generates the object data 22 from these echo signals 44 by means of the visibility module 12. In this way, the optical laws of reflection and refraction are used to determine the course of the chirp and echo signals 42, 44.

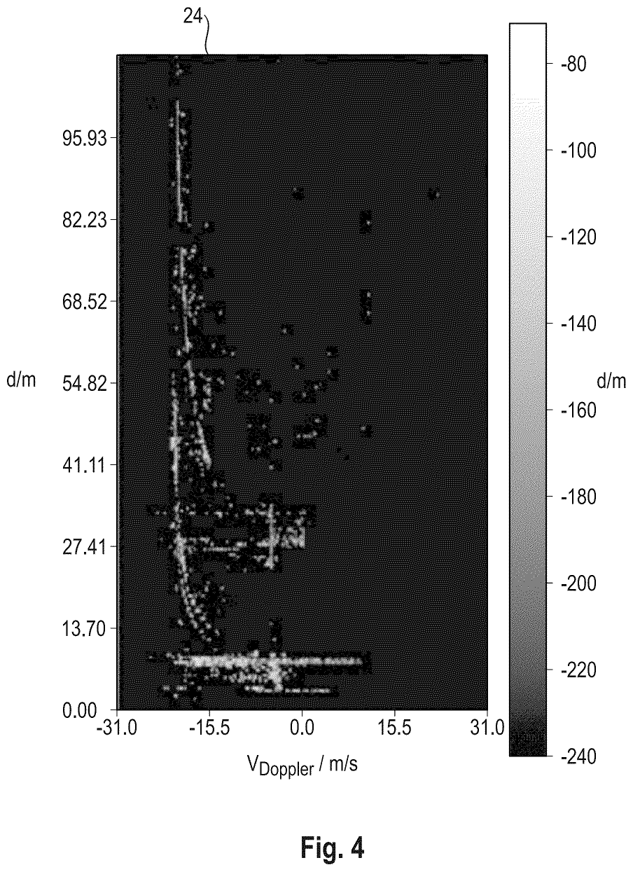

FIG. 4 shows the first mapping 24, which is formed as the first range-Doppler map 24. The first range-Doppler map 24 shows the Doppler velocity in meters per second on the abscissa and the range in meters between the sensor 38 and the respective objects O1-O6. Once again, a third dimension is the brightness of the displayed objects O1-O6, whereas on the right, a relationship between this intensity and a numerical value is shown.

The first mapping 24 contains the information as determined by the mapping module 14 from the object data 22. Only the local maxima from the first range-Doppler map are entered. This first range-Doppler map can be created immediately because all the information required for it is ready and ready for retrieval in the object data 22.

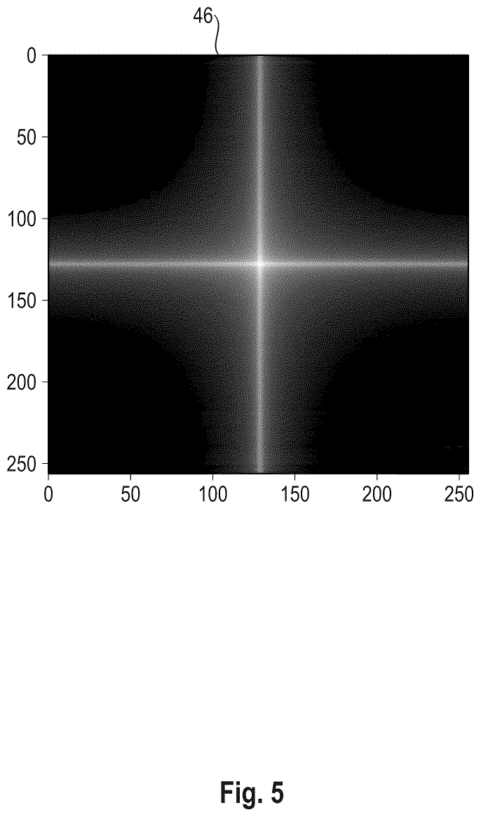

FIG. 5 shows a characteristic function 46 for a sensor, which is designed as a point spread function. The point spread function is a response of a sensor to an ideal point-shaped object. Such a characteristic function 46 can be measured and/or analytically described for the sensor, such as a radar sensor or lidar sensor. The point spread function describes how the respective point-shaped object is mapped by the sensor.

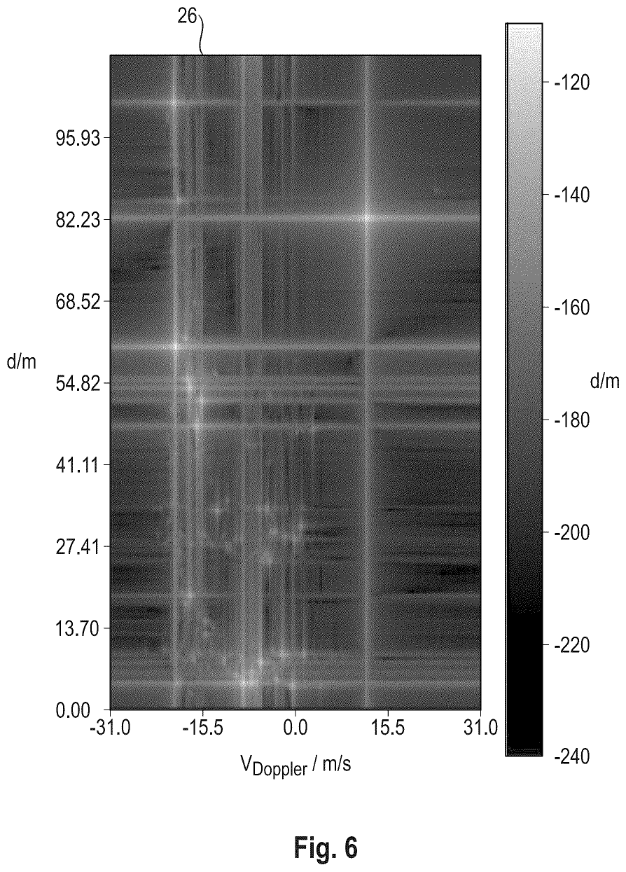

By a convolution of the characteristic function 46 of FIG. 5 with the first range-Doppler map 24 of FIG. 4, the second range-Doppler map 26 of FIG. 6 is determined by the link module 16.

Smearing is then added to the first range-Doppler map 24 (FIG. 4), so that the second range-Doppler map 26 (FIG. 6) is generated.

From the first range-Doppler map 24, the second mapping 26 is created by convolution with the characteristic function 46, which is realistic because it takes into account mapping properties of the sensor to be simulated.

FIG. 6 shows the second mapping 26 with the desired smearing of the applied signals. On the right, the transfer of the brightness of the applied signals, the peaks, into a numerical value is shown. The detected objects O1-O6 can be seen as brightly shining local maxima. Each object O1-O6 is flanked by a cross-shaped smearing along both axes. This smearing does not represent a physical reality of the sensor environment, but rather artifacts of the sensor 38 that are created by the time-limited analysis intervals of the raw data when performing the Fourier transforms.

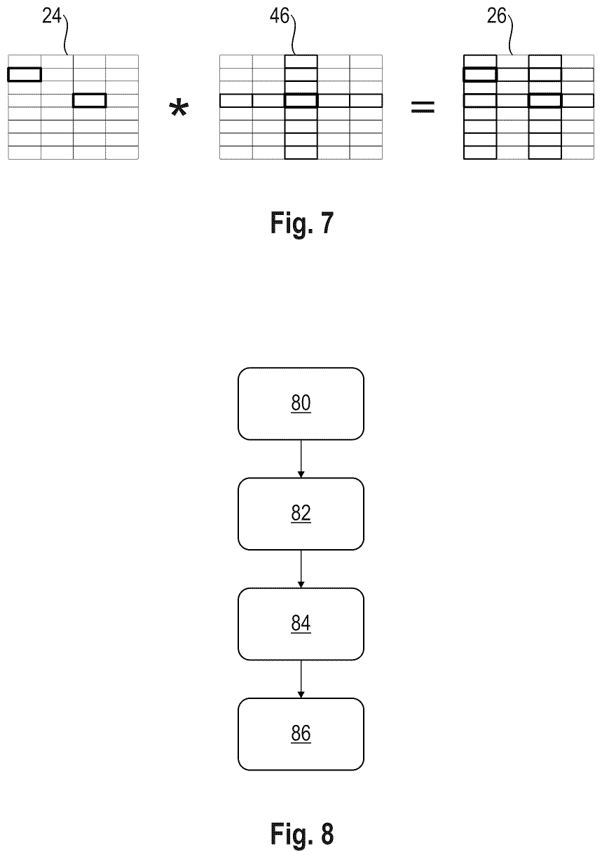

FIG. 7 schematically shows how the convolution takes place. In this process, the first mapping 24 with the characteristic function 46 is convoluted, and the second mapping 26 with the corresponding surfaces is created. The smearing around the two dark fields can be clearly seen, wherein the smearing is caused by the properties of the sensor 38.

FIG. 8 shows in a flow chart the method according to this application.

In step 80, the object data 22 for at least one virtual object O1 to O6, which is located in a virtual environment 30, is generated as a function of the sensor 38. For this purpose, for example, a ray tracing method described in relation to FIG. 2 and FIG. 3 can be used. This method step 80 is carried out, for example, by the visibility module 12.

In step 82, at least two parameters of the at least one virtual object O1-O6 are determined, namely from the object data 22. The virtual objects O1-O6 are then displayed as a function of the at least two parameters in the first mapping 24. This method step 82 is carried out, for example, by the mapping module 14.

In step 84, the first mapping 24 is transferred to the second mapping 26, taking into account a characteristic function 46 of the sensor 38, wherein in the second mapping 26, the at least one virtual object O1-O6 is shown as a function of the at least two parameters. This method step 84 is carried out, for example, by the link module 16.

In step 86, the second mapping 26 is converted into synthetic sensor data 32 and the synthetic sensor data 32 is provided for output. This method step 86 is carried out, for example, by the output module 20.

The invention being thus described, it will be obvious that the same may be varied in many ways. Such variations are not to be regarded as a departure from the spirit and scope of the invention, and all such modifications as would be obvious to one skilled in the art are to be included within the scope of the following claims

What is claimed is:

1. A simulator for simulating a sensor for object detection, the sensor comprising an active sensor which is set up to generate raw sensor data by emitting a chirp signal and receiving an echo signal, the simulator being configured to generate synthetic sensor data of the sensor via the simulation, the simulator comprising:
a visibility module to generate object data for at least one virtual object located in a virtual environment as a function of the sensor;
a mapping module to determine at least two parameters of the virtual object from the object data and to represent at least one virtual object as a function of the at least two parameters in a first mapping;
a link module to transfer the first mapping to a second mapping, taking into account a characteristic function of the sensor, wherein in the second mapping to determine the second mapping from the sensor raw data, the at least one virtual object is shown as a function of the at least two parameters;
a recalculation module set up to determine synthetic sensor raw data from the second mapping, the determination of the synthetic sensor raw data being a function of the sensor for object detection and has an inverse Fourier transform; and
an output module to provide the synthetic sensor raw data for output.

2. The simulator according to claim 1, wherein the first mapping has a first range-Doppler map, and the second mapping has a second range-Doppler map.

3. The simulator according to claim 1, wherein the characteristic function has a point spread function of the sensor and the link module is configured to transfer the first mapping to the second mapping by executing a convolution function with the point spread function, and wherein the convolution function comprises a convolution.

4. The simulator according to claim 1, wherein the simulated sensor is assigned a virtual position in the virtual environment and the visibility module is configured to generate the object data for the at least one virtual object cyclically, taking into account the respective virtual position.

5. The simulator according to claim 4, wherein the object data for a respective virtual object includes a representation of a respective virtual echo signal of a respective virtual chirp signal on the respective virtual object.

6. The simulator according to claim 1, wherein the synthetic sensor data is designed such that the object data is derived from it by the sensor.

7. A method for simulating a sensor for object detection, wherein the sensor has an active sensor which is configured to generate raw sensor data by emitting a chirp signal and receiving an echo signal, wherein the simulation generates synthetic sensor data of the sensor, the method comprising:
generating object data for at least one virtual object located in a virtual environment as a function of the sensor;
determining at least two parameters of the virtual object from the object data;
representing the at least one virtual object as a function of the at least two parameters in a first mapping;
transferring the first mapping to a second mapping by taking into account a characteristic function of the sensor, wherein, in the second mapping, the at least one virtual object is represented as a function of the at least two parameters;
determining synthetic sensor raw data from the second mapping, the determination of the synthetic sensor raw data being a function of the sensor for object detection and having an inverse Fourier transform; and
providing the synthetic sensor raw data for output.

8. The method according to claim 7, wherein the first mapping has a first range-Doppler map, and the second mapping has a second range-Doppler map.

9. The method according to claim 7, wherein the characteristic function has a point spread function of the sensor, wherein the first mapping is transferred to the second mapping by executing a convolution function with the point spread function, and wherein the convolution function includes a convolution.

10. The method according to claim 7, wherein the sensor for object detection has an active sensor that generates raw sensor data by emitting a chirp signal and receiving an echo signal and determines the second mapping from the sensor raw data.

11. The method according to claim 7, wherein a virtual position is assigned to the simulated sensor in the virtual environment, and wherein the object data for the at least one virtual object is generated cyclically, taking into account the respective virtual position.

12. A computer program product, comprising commands which, when the program is executed by a computer, cause the computer to perform the steps of the method according to claim 7.
